(19) United States
(12) Patent Application Publication
(10) Pub. No.: US 2016/0183393 A1
(43) Pub. Date: Jun. 23, 2016

(54) MOUNTING APPARATUS FOR ELECTRONIC DEVICE AND USE THEREOF

(71) Applicant: ALTER BLUE CREATIVE LLC, Columbus, OH (US)

(72) Inventors: Marc Timothy Groom, Columbus, OH (US); Spencer Eugene Samuel Bardsley, Columbus, OH (US)

(21) Appl. No.: 14/850,498

(22) PCT Filed: Mar. 17, 2014
(86) PCT No.: PCT/US14/30857

§ 371 Date: Sep. 10, 2015

Related U.S. Application Data
(60) Provisional application No. 61/800,877, filed on Mar. 15, 2013.

(51) Int. Cl. H05K 5/02; B62B 3/14; H05K 5/00; F16B 1/00; F16M 13/02

(52) U.S. Cl. CPC H05K 5/0204; F16B 1/00; F16M 13/022; H05K 5/0086; B62B 3/1472; F16B 2001/0035

(57) ABSTRACT

Mounting apparatus for securing an electronic device to facilitate operation of the device by a user in a hands-free manner are disclosed herein, as well as kits comprising and methods of using the same. Many electronic devices that are designed for handheld use (e.g., mobile phones, tablet devices, or the like) provide useful functionalities in a variety of activities that are not conducive to handheld use, particularly when considering that typical handheld use often requires availability of both hands (i.e., one hand to hold the device and the other hand for operating the device, e.g., interacting with a touchscreen user interface).

### CROSS-REFERENCE TO RELATED APPLICATIONS

This application claims priority from U.S. Provisional Patent Application No. 61/800,877, entitled “Mounting Systems for Handheld Electronic Devices” and filed on Mar. 15, 2013, the contents of which are incorporated by reference herein in their entirety.

### BACKGROUND OF THE INVENTION

Many electronic devices that are designed for handheld use (e.g., mobile phones, tablet devices, or the like) provide useful functionalities in a variety of activities that are not conducive to handheld use, particularly when considering that typical handheld use often requires availability of both hands (i.e., one hand to hold the device and the other hand for operating the device, e.g., interacting with a touchscreen user interface). Existing mounts for such devices are, however, unsatisfactory for all applications and further mount functionality is desirable.

### BRIEF SUMMARY OF THE INVENTION

Advantageously, mounting apparatus of the invention provide improved functionality and ease of use. Not only are such mounting apparatus adaptable, without modification in exemplary embodiments, to adequately secure a range of electronic devices types and sizes (e.g., a portable consumer electronic device selected from personal data assistants, phones, and personal computers), but they are also adaptable, with little or no modification, for attachment to a wide range of surfaces (e.g., a surface on a shopping trolley) and for efficient use of devices in a wide range of applications (e.g., for operation of the device while driving a motorized vehicle or for operation of the device by a user simultaneously while exercising).

A mounting apparatus for securing an electronic device to facilitate operation of the device by a user in a hands-free manner according to the invention comprises: a base portion configured for attachment of the mounting apparatus to a surface (e.g., the base portion comprises a magnetic sub-component for attachment to the surface) and a holder portion comprising a flexible and fatigue resistant material adjacent the base portion and configured to enable single-handed securing of the device therein by constraining the device only along a portion of two longest opposing side edges of the device without substantially obscuring a front side of the device and such that a gap exists between a back side of the device and the holder portion (e.g., the gap providing a distance between the back side of the device and the mount of about 1.0 centimeter to about 2.4 centimeters), wherein the holder portion has a maximum inner diameter in a relaxed state that is smaller than a width dimension of the device.

In one embodiment, the mounting apparatus is a single component comprising the base portion and the holder portion. In another embodiment, the mounting apparatus comprises at least two components, one of the at least two components comprising the base portion and another one of the at least two components comprising the holder portion.

Advantageously, configuration of the holder portion of the mounting apparatus specifically facilitates improved functionality of the mount, including adaptability of the mount for securing a range of devices single-handedly. Dimensions of the holder portion can vary. In one embodiment, width of the holder portion is about 1.3 centimeters to about 7.6 centimeters. In one embodiment, the holder portion has a maximum thickness of 0.25 centimeter to about 2.54 centimeters.

The holder portion advantageously comprises a flexible and fatigue resistant material—e.g., a material selected from acrylonitrile butadiene styrene, high-density polyethylene, and thermoplastic elastomer materials. According to one aspect of this embodiment, Young's Modulus of the flexible and fatigue resistant material is about 0.1-8.0 GPa. According to another aspect of this embodiment, ultimate tensile strength of the flexible and fatigue resistant material is about 12-90 MPa.

In an exemplary embodiment, the mounting apparatus is capable of use with a range of small devices, wherein width of the devices in the range is about 2.5-8.9 centimeters. According to another exemplary embodiment, the mounting apparatus is capable of use with a range of medium devices, wherein width of the devices in the range is about 6.4-12.7 centimeters. According to yet another exemplary embodiment, the mounting apparatus is capable of use with a range of large devices, wherein width of the devices in the range is about 10.2-20.3 centimeters.

In one embodiment, the mount is capable of providing a holding force through flexion of about 8-67 Newtons when the device is secured within the mount. Securement of a device within mounting apparatus of the invention can be further improved in alternative embodiments. According to a further embodiment, the holder portion has at least one protrusion at each of two opposing edges adjacent an opening of the holder portion. An inner surface of the holder portion adjacent the opposing protrusions slopes inward according to an exemplary aspect of this embodiment. The mounting apparatus further comprises a gripping component (e.g., having a maximum thickness of about 1.30 millimeters to about 1.30 centimeters) on at least a portion of an inner surface of the holder portion according to another embodiment. According to an exemplary aspect of this embodiment, the gripping component comprises a material having a Shore D hardness of less than about 55. According to another exemplary aspect of this embodiment, the gripping component comprises a material having a Shore A hardness of about 3090. According to yet another exemplary aspect of this embodiment, the gripping component has less than about 25% compression set after being compressed at room temperature for about 22 hours when tested according to ASTM D 395.

Kits comprising mounting apparatus of the invention can draw upon adaptability of the mounts. In one embodiment, a kit comprises the base portion and at least two of the holder portions, wherein the holder portions are interchangeable with the base portion to form the mounting apparatus. In another embodiment, a kit comprises the holder portion and at least two of the base portions, wherein the base portions are interchangeable with the holder portion to form the mounting apparatus.

A method of using the mounting apparatus comprises: attaching the mounting apparatus to a first surface; securing the device therein; optionally, operating the device in a hands-free manner; optionally, detaching the mounting apparatus from the first surface; optionally, attaching the mounting apparatus to a second surface; and, optionally, operating the device in a hands-free manner. According to one aspect of the invention, the device can be secured in the mounting apparatus such that the mounting apparatus functions as a stand from which the device can extend upward. According to another aspect of the invention, the device is secured within the mounting apparatus in a generally horizontal orientation. Further embodiments of methods of the invention comprise the step of tilting the device from the generally horizontal orientation.

Another improved mounting apparatus for securing an electronic device to facilitate operation of the device by a user in a hands-free manner comprises: a base portion configured for attachment of the mounting apparatus to a surface; a holder portion adjacent the base portion and comprising a flexible and fatigue resistant material; and communications functionality housed within at least one of the base portion and the holder portion and enabling data communication between the mount and the device when secured in the mount. According to an exemplary aspect of this embodiment, the communications functionality comprises a passive component—e.g., a NFC chip or RFID tag. According to another exemplary aspect of this embodiment, the communications functionality is limited to nonprogrammable actions, operating based on one or more preset programs. Stores using shopping trolleys comprising such mounting apparatus attached to at least one surface thereon are capable of, for example, drawing upon the mounts to increase sales or otherwise generate more revenue.

### BRIEF DESCRIPTION OF THE SEVERAL VIEWS OF THE DRAWINGS

FIG. 1A is a perspective view of one embodiment of a mounting apparatus according to the present invention.

FIG. 1B is a side view of the mounting apparatus of FIG. 1A.

FIG. 1C is a front view of the mounting apparatus of FIG. 1A.

FIG. 1D is a perspective view of the mounting apparatus of FIG. 1A with a horizontally oriented device secured therein.

FIG. 1E is a perspective view of the mounting apparatus of FIG. 1A with a vertically oriented device secured therein on a vertical surface.

FIG. 1F is a front view of the mounting apparatus of FIG. 1A with a device secured therein in a horizontal orientation.

FIG. 1G is a side view of the mounting apparatus of FIG. 1A with a device secured therein in a horizontal orientation.

FIG. 1H is a side view of the device secured in the mounting apparatus of FIG. 1G, but with the device angled in the mounting apparatus as compared to that orientation shown in FIG. 1G.

FIG. 1I is a side view of the device secured in the mounting apparatus of FIG. 1G, but with the device angled in the mounting apparatus as compared to those orientations shown in FIGS. 1G-1H.

FIG. 1J is a perspective view of a device secured in the mounting apparatus of FIG. 1G, but with the mounting apparatus positioned to secure the device in a vertical orientation on a horizontal surface.

FIG. 2A is a side view of a single-component mounting apparatus of the invention.

FIG. 2B is a side view of a multi-component mounting apparatus of the invention.

FIG. 2C is a perspective view of the mounting apparatus of FIG. 2A, wherein a magnetic component is included in the base portion thereof.

FIG. 3A is a side view of a mounting apparatus of the invention wherein the holder portion is flexed inward from its relaxed state to an overlapping position.

FIG. 3B is a side view of a mounting apparatus of the invention wherein the holder portion is flexed outward from its relaxed state.

FIG. 4A is a perspective view of one embodiment of a holder portion of a mounting apparatus of the invention.

FIG. 4B is a side view of the holder portion illustrated in FIG. 4A.

FIG. 5A is a C-shaped side profile for an exemplary embodiment of a holder portion of a mounting apparatus of the invention.

FIG. 5B is a block C-shaped side profile for an exemplary embodiment of a holder portion of a mounting apparatus of the invention.

FIG. 5C is a V-shaped side profile for an exemplary embodiment of a holder portion of a mounting apparatus of the invention.

FIG. 5D is a half hexagon-shaped side profile for an exemplary embodiment of a holder portion of a mounting apparatus of the invention.

FIG. 5E is an angle in-shaped side profile for an exemplary embodiment of a holder portion of a mounting apparatus of the invention.

FIG. 5F is an angle out-shaped side profile for an exemplary embodiment of a holder portion of a mounting apparatus of the invention.

FIG. 5G is a half octagon-shaped side profile for an exemplary embodiment of a holder portion of a mounting apparatus of the invention.

FIG. 5H is an open diamond-shaped side profile for an exemplary embodiment of a holder portion of a mounting apparatus of the invention.

FIG. 5I is a U-shaped side profile for an exemplary embodiment of a holder portion of a mounting apparatus of the invention.

FIG. 5J is an angle in gripper-shaped side profile for an exemplary embodiment of a holder portion of a mounting apparatus of the invention.

FIG. 5K is an angle out gripper-shaped side profile for an exemplary embodiment of a holder portion of a mounting apparatus of the invention.

FIG. 5L is a tall C-shaped side profile for an exemplary embodiment of a holder portion of a mounting apparatus of the invention.

FIG. 5M is a tall C gripper-shaped side profile for an exemplary embodiment of a holder portion of a mounting apparatus of the invention.

FIG. 5N is a w-shaped side profile for an alternative exemplary embodiment of a holder portion of a mounting apparatus of the invention.

FIG. 6A is a side view of an alternative embodiment of a holder portion of a mounting apparatus of the invention, wherein a gripping component is included therein.

FIG. 6B is a side view of an alternative embodiment of the holder portion illustrated in FIG. 6A.

FIG. 7A is a perspective view of an exemplary mounting apparatus of the invention.

FIG. 7B is a perspective view of an alternative embodiment of the mounting apparatus of FIG. 7A.

FIG. 7C is a perspective view of the mounting apparatus of FIG. 7B attached to a shopping trolley.

FIG. 7D is a perspective view of a device secured within the mounting apparatus of FIG. 7C.

FIG. 8 is a side view of a mounting apparatus of the invention comprising communications functionality.

### DETAILED DESCRIPTION OF THE INVENTION

A novel mounting apparatus (also referred to herein as a “mount”) for an electronic device (also referred to herein as a “device”) is described further herein. Devices capable of being mounted within apparatus of the invention include a display for viewing data and/or images thereon.

Advantageously, mounting apparatus of the invention are capable of use with a wide variety of electronic devices, such as consumer electronic devices. In addition, mounts of the invention may be used to hang, hold, stand up, grip, lock, or support other objects (e.g., a remote control, a bottle, a guitar, tools, a hose, a pipe, clothing, jewelry, headphones, equipment, or baggage). However, benefits of the invention are generally realized by use of the mounting apparatus for mounting of electronic devices.

In some embodiments, the mounting apparatus is not device-specific. Rather, in exemplary embodiments, the mount is a universal mount that is capable of use with one or more classes of devices, as delineated by width of devices within each class. In alternate embodiments, the mount is capable of use with a specific range of devices within a certain class of device (e.g., small, medium, or large) or with a specific device. In preferred embodiments, use of a mount universally in such a manner can be done without modification of the mount. Thus, functionality of mounts of the invention in that regard is advantageously improved as compared to many conventional mounting apparatus.

Exemplary consumer electronic devices are generally portable and include those widely marketed as personal data assistants, phones (e.g., cellular, satellite, and other cordless phones), personal computers, and the like. For example, laptop computers, notebook computers, tablet computers, portable music players, smartphones, GPS devices, radios, e-readers, calculators, game consoles, clocks, timers, digital photo albums, microphones, cameras (e.g., still or video cameras), monitors, transceivers, scanners, and identifiers (e.g., RFID identifiers) are such consumer electronic devices. Many of these devices are generally mobile and, as such, are understood to be handheld electronic devices. Use of the disclosed mount in conjunction with such devices is relatively quick and easy. In preferred embodiments of the invention, devices are capable of being secured within a mounting apparatus single-handedly (i.e., requiring only one hand for the same, although both of a user's hands can be used) and thereafter operated in a hands-free manner.

While not limited to handheld electronic devices, mounting apparatus of the invention have been found particularly beneficial for use with electronic devices that are designed for handheld use. One of the benefits of mounting apparatus of the invention is their ease of adaptability to a wide variety of, not only devices, but also applications for those devices. For example, mounts of the invention can be used in situations where use of a device is desired or needed, but holding of the device is not desired or allowed. A notable situation where mounts of the invention can be advantageously employed is for operation of a cellular phone while driving a motorized vehicle. Other exemplary situations include those where a device is used by one exercising, cooking, playing an instrument, biking, recording, shopping, engaging in a conference call, performing do-it-yourself or manual tasks that require coinciding task instruction, speaking in public using the device as a teleprompter, or otherwise desiring use of their hands for activities other than operating the device. Such situations also include those where a device is used to assist with any of the following exemplary tasks: making a phone call in general, using application software (i.e., an app), playing a game, organizing tasks, ascertaining weather, setting an alarm, watching a clock, note taking, recording voice notes, using social networks, sending and receiving messages such as texts and e-mails, locating GPS coordinates, obtaining map directions, video conferencing, listening to music, recording audio, editing audio, reading news, watching movies, recording video, editing video, using a flashlight, accessing the Internet, using an Internet search engine, speaking from a teleprompter, watching or listening to a baby monitor, finding nearby items, reading, photographing, scanning, making a payment, calculating, drawing, shopping, cooking, banking, or otherwise computing in general. Functionality of mounts in this regard is advantageously improved as compared to that of most conventional mounts.

When evaluating whether the mounting apparatus is capable of use with a specific device, consideration of any accessories positioned on the exterior of the device may be necessary. For example, a wide variety of protective and/or decorative cases are marketed for many consumer electronic devices. The dimensions and materials used for such cases can vary widely. In certain embodiments, mounting apparatus of the invention designed for use with a specific range of devices or with a specific device can accommodate devices positioned within its respective case or similar accessory. It is to be understood, however, that there may be circumstances where use of the device with specific accessories causes it to be incapable of use with its respective mounting apparatus. In those embodiments where the mount accommodates device cases and similar accessories, the mount is capable of accommodating devices as used with a majority of cases marketed for use with that device. There are exceptional circumstances, however, where specific cases and similar accessories deviate from the norm to the extent that the mount is not capable of effective use with devices outfitted with such accessories.

Mounting apparatus of the invention can be configured for use in conjunction with a wide range of surfaces, often with little or no modification being required when moving the mount between surfaces. Understand that the surfaces with which mounting apparatus of the invention can be used include those associated with specific objects (e.g., supports). Exemplary objects to which mounts of the invention can be attached include those shaped as a rounded cylinder (e.g., a pole, a railing, a handlebar, etc.), those including a screw or receptacle therefor (e.g., a screw-mount on a tripod), or those having a semi-flat surface (e.g., a wall, a desktop, etc.). Again, functionality of mounts in this regard is advantageously improved as compared to that of most conventional mounts. Depending on user desires and configuration of the mounting apparatus, a mount is typically positioned on a surface in a manner facilitating hands-free use of a device when mounted therein.

Exemplary surfaces on which mounts of the invention can be used include those associated with the following objects: a shopping trolley (sometimes referred to as a shopping cart, and which includes a handlebar, crossbar for a handlebar, side, and even a child seat in certain embodiments), a stroller, a non-motorized vehicle (e.g., a bicycle, a cart, or a wheelchair), a motorized vehicle (e.g., an automobile, a truck, a motorcycle, an ATV, a forklift, various construction equipment, a boat, an airplane, a train, or a bus) or component thereof (e.g., a dashboard or dashboard vent on an automobile), furniture (e.g., a desk, a table, a chair, a cabinet, or a bed such as a hospital bed), a stand, a belt, a tripod, a backpack, exercise equipment (e.g., a treadmill, an elliptical machine, a stationary bike, a weight machine such as a weight rack or bench, a TRX station, a training rig, a kettlebell, or a free weight), musical equipment (e.g., an amplifier, a keyboard stand, a music stand, a keyboard, a piano, a guitar, a drum set, or other musical instrument), a computer, a television, an appliance, a tree, an easel, a conveyor, a ladder, a railing, or a multitude of other objects on which mounting of a device is desired.

In one embodiment, the mount is positioned on a surface in a repositionable manner (i.e., in a manner requiring no releasing adjustment of mechanical or adhesive components on the mounting apparatus in order to move the mount to a different position on that surface or to another surface). For example, mounting apparatus according to this embodiment can be simply picked up with minimal effort by a user and placed in a different location. In another embodiment, the mount is positioned on a surface in a fixed manner (i.e., in a manner requiring releasing adjustment of mechanical or adhesive components on the mounting apparatus in order to move the mount to a different position on the surface). For example, mounting apparatus according to this embodiment may need loosening of a screw, de-bonding of an adhesive, or other releasing adjustment before they can be picked up with minimal effort by a user and placed in a different location.

The mount is configured for attachment to a surface, with different configurations depending on the nature of the surface to which it is intended to be attached and the type of attachment mechanism desired. In one embodiment, a mount is designed to typically secure a device in one particular orientation, both with respect to basic orientation of a device within the mount and with respect to orientation of the mount securing the device in relation to the environment in which the mount is used. According to another embodiment, a mount is designed to secure a device in one basic orientation within the mount, but in one of multiple orientations with respect to the environment in which the mount is used when the device is secured therein. The latter embodiment includes use of an adapter (i.e., an individual component coupled between the base portion of the mount and the surface to which the mount is attached) according to further embodiments of the invention.

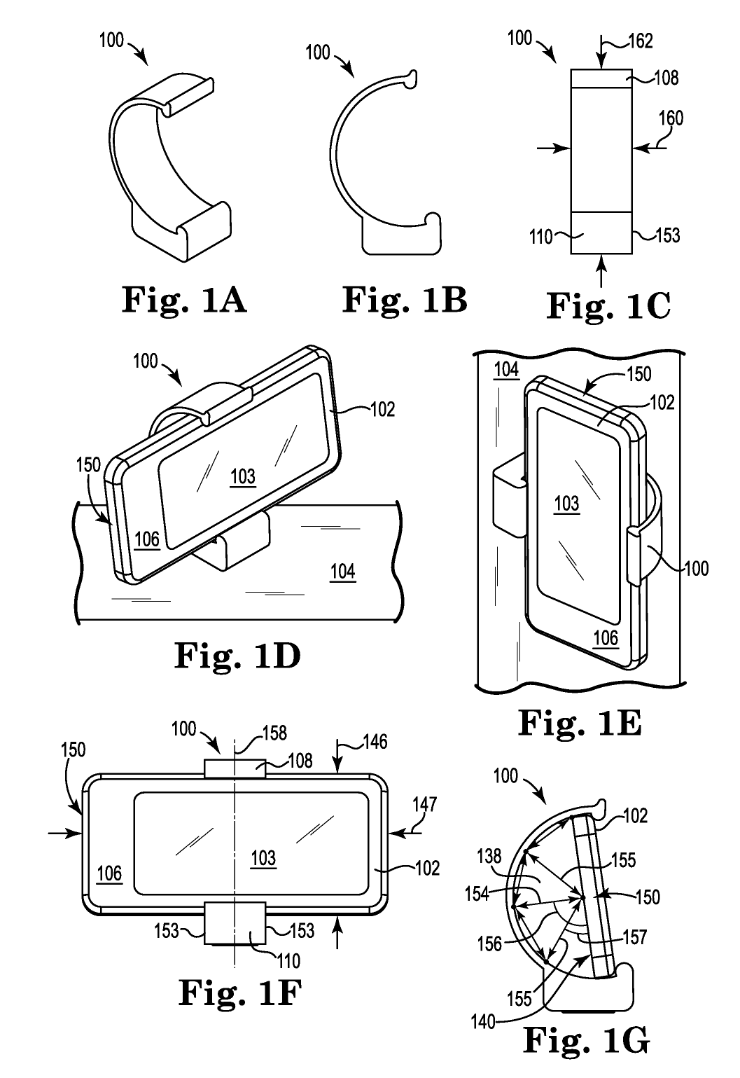

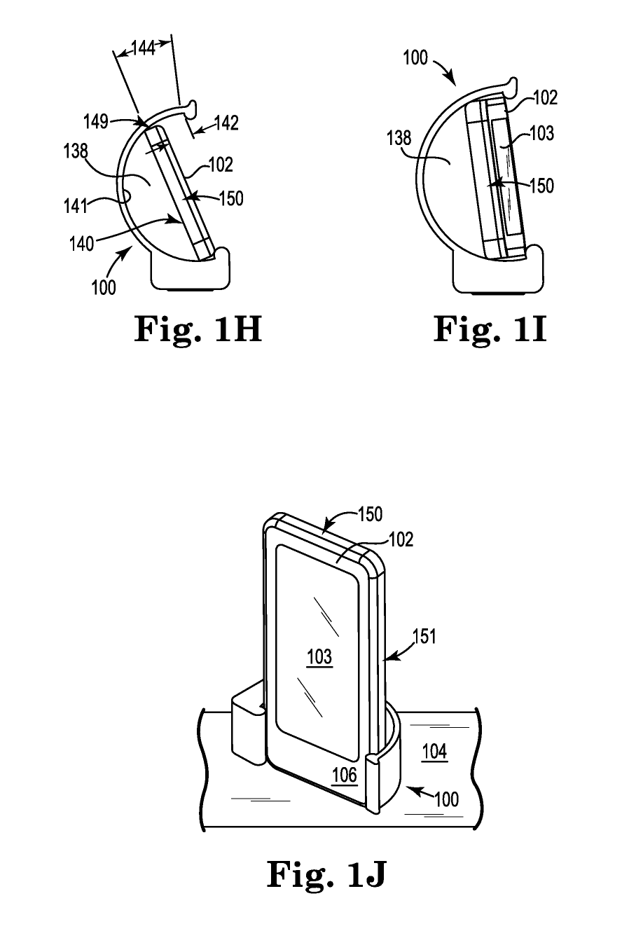

FIGS. 1A-1J illustrate one embodiment of a mounting apparatus 100 for securing a device 102 according to the invention and attaching the mount 100 to a surface 104. A device 102 can be secured within the mount 100 such that it is generally positioned horizontal in relation to the environment in which the mount is used, as illustrated in FIG. 1D. By “horizontal,” it is to be understood that the longest side edge 151 of the device 102 (which typically has a rectangular shape when viewed from the front side 106) is disposed horizontally (i.e., in a landscape orientation when viewed from the perspective of an individual standing upright on level ground) when the mounting apparatus 100 is attached to a surface 104. In another embodiment, as illustrated in FIG. 1E, a device 102 can be secured within a mount 100 such that it is generally positioned vertical. By “vertical,” it is to be understood that width dimension 146 of the device 102 is disposed vertically (i.e., in a portrait orientation when viewed from the perspective of an individual standing upright on level ground) when the mounting apparatus 100 is attached to a surface 104.

As illustrated in FIGS. 1F-1G, a device 102 is generally secured in a horizontal orientation within the mount 100. Orientation within the mount 100 is to be understood as that basic orientation when viewed from the front of the mount 100 positioned as illustrated in FIG. 10. While orientation within the mount 100 is generally horizontal, position of a device 102 secured within the mount 100 can deviate from that basic orientation as desired.

According to a further embodiment of the invention, a mount 100 is designed to allow for easy adjustment of a device's orientation within the mount 100 by a user. For example, as illustrated in FIG. 1H, a device 102 is secured within the mount 100, but tilted backward by sliding the top 149 of the device 102 along inner surface 141 of the holder portion 108 (as described further below) a desired distance 142 from its general horizontal orientation to an angle 144 (e.g., an angle of up to about fifteen degrees) from the general horizontal orientation of the device 102. In another example, as illustrated in FIGS. 11-11, a device 102 is secured within the mount 100, but translated from the general horizontal orientation illustrated in FIG. 1G by pushing or pulling one side 150 of the device 102 to an angle 148 (e.g., an angle of up to about fifteen degrees) from the general horizontal orientation of the device 102. Recognize that the side of the device that is pushed or pulled to provide such translation can also be the side that is opposite side 150 denoted in FIGS. 1D-1J. Tilting (also referred to herein as translation) of the device 102 in this manner is easy, can be done single-handedly, and does not affect ability of the mount 100 to secure the device 102 at the desired orientation within the mount 100.

In all cases, a device 102 is advantageously oriented within the mount 100 such that the device 102 is constrained by the mount 100 (e.g., at the holder portion of the mount 100, as described further below) only along a portion of two longest opposing side edges 151 of the device 102. Advantageously, simply, and in contrast to many conventional mounting apparatus, no physical contact is necessary or occurs between the device 102 and the mount 100 along the device's longitudinal axis. Further, minimal to no physical contact occurs between the device 102 and the mount 100 along the back side 140 of the device 102.

As illustrated in FIG. 1G, when a device 102 is secured within a mount 100 according to the invention, a gap 138 is formed between the device 102 and the mount 100. The gap 138 is formed as essentially the entire back side 140 of the device 102 makes no physical contact with the mount 100. In an exemplary embodiment, the gap 138 (as measured at an angle 156 of about ninety degrees with respect to the back side 140 of the device 102) provides a distance 154 between the back side 140 of the device 102 and the mount 100 of about 1.0 centimeter (0.4 inch) to about 2.4 centimeters (1.0 inch). In a further exemplary embodiment, the gap 138 (as measured at an angle 157 of about forty-five degrees with respect to the back side 140 of the device 102) provides a distance 155 between the back side 140 of the device 102 and the mount 100 of about 1.2 centimeters (0.5 inch) to about 2.4 centimeters (1.0 inch). This novel gap 138 was found to provide an optimal balance of properties and functionality for mounts 100 of the invention.

Unlike conventional mounting apparatus, mounts 100 of the invention providing for such a gap 138 when a device 102 is secured therein have improved functionality. For example, such a design facilitates flexibility in what types and sizes of devices 102 the mount 100 can securely hold. Further, such a design facilitates selective repositioning of a device 102 within the mount 100 as desired by a user of the device 102 and as described above with respect to FIGS. 1F-1I and as described below with respect to FIG. 1J.

According to one aspect of the invention, the device 102 is capable of being selectively slid along its longest side edges 151 and within the mount 100 as desired by a user of the device 102. Recognize that the device 102 is generally positioned such that the mount 100 constrains only a portion of two longest opposing side edges 151 of the device 102 proximate the centerline 158 of the device 102, as illustrated in FIGS. 1D-1F. In alternate embodiments, however, the device 102 is positioned within the mount 100 such that the mount 100 constrains only a portion of two longest opposing side edges 151 of the device 102 at one end of the device 102, as illustrated in FIG. 1J. In this manner, the mount 100 can be attached to a horizontal surface such that it is positioned on its side 153 and the device 102 is positioned in a vertical orientation in relation to the environment in which it is used. The mount 100 not only secures the device 102 in this embodiment, but it also functions as a simple stand from which the device 102 can extend upward in an unfettered manner. Positioning of the device 102 within the mount 100 in this manner is easy, can be done single-handedly, and does not affect ability of the mount 100 to secure the device 102 at the desired orientation within the mount 100. For example, a device 102 secured within a mount 100 functioning as a stand, as illustrated in FIG. 1J can be tilted within the mount 100 as described above with respect to FIGS. 1H-1I.

Mounting apparatus of the invention may have one or multiple individual components and can be attached to a surface via any suitable portion thereof. In one embodiment, a mount comprises a holder portion and a base portion. The holder portion secures (i.e., holds) the device within the mount and the base portion secures (i.e., attaches) the mount to a surface directly or indirectly, as is the case when an adapter is used. Each of these portions may comprise multiple parts (also referred to herein as sub-components). In order to maximize benefits of the invention, however, at least the holder portion of a mount according to the invention does not include sub-components.

Structural components of the mount can be made from any suitable material according to methodology known to those of ordinary skill in the art. For example, mounts and individual components thereof can be made from plastic, rubber, metal, wood, or combinations thereof. To facilitate obtainment of relatively lightweight mounts, which are beneficially used in certain applications, and for adequately securing devices therein, use of flexible and fatigue resistant materials (i.e., a material capable of flexure, but developing relatively low fatigue strain over a high number of cycles), such as certain plastic and/or rubber materials, within the mount is preferred. Fatigue resistant materials as used herein refers to materials that remain flexible through at least about 10,000 cycles when tested using Dynamic Mechanical Analysis (DMA) based on ASTM D 4065. A material is understood to remain flexible if less than about 25% fatigue strain develops in the material when tested as such. Preferably, fatigue resistant materials of the invention remain flexible through at least about 500,000 cycles when tested as such. Further preferred are fatigue resistant materials wherein less than about 10% fatigue strain develops in the material when tested as such. Exemplary flexible and fatigue resistant materials include those within the following classes of materials: acrylonitrile butadiene styrene (ABS), high-density polyethylene (HDPE), and thermoplastic elastomer (TPE). Such materials are commercially available from a number of sources, including HDPE marketed by Legacy Polymer Products (Dunmore, Pa.) and TPE marketed by RTP Co. (Winona, Minn.) using the trade designation, RTP 6001-70A.

Depending on the type of material being formed into the mount or individual components thereof, various processes such as milling, computer numerical control (CNC) machining, injection molding, extruding, casting (e.g., die casting), cold rolling, three-dimensional (3D) printing, bending, welding, forging, laminating, or stereo lithography can be used to form the same. When the mount includes multiple components, each of the individual components may be formed using the same or different materials and processes. In general, however, to provide functionality according to the present invention, the holder portion is formed from materials and in a shape suitable for securing a desired device or range of devices within the mount. In one embodiment, the holder portion specifically comprises a flexible and fatigue resistant material selected to provide adequate holding force on a specific device or range of devices to be used with the mount. Preferably, the holder portion comprises ABS, HDPE, and/or TPE materials.

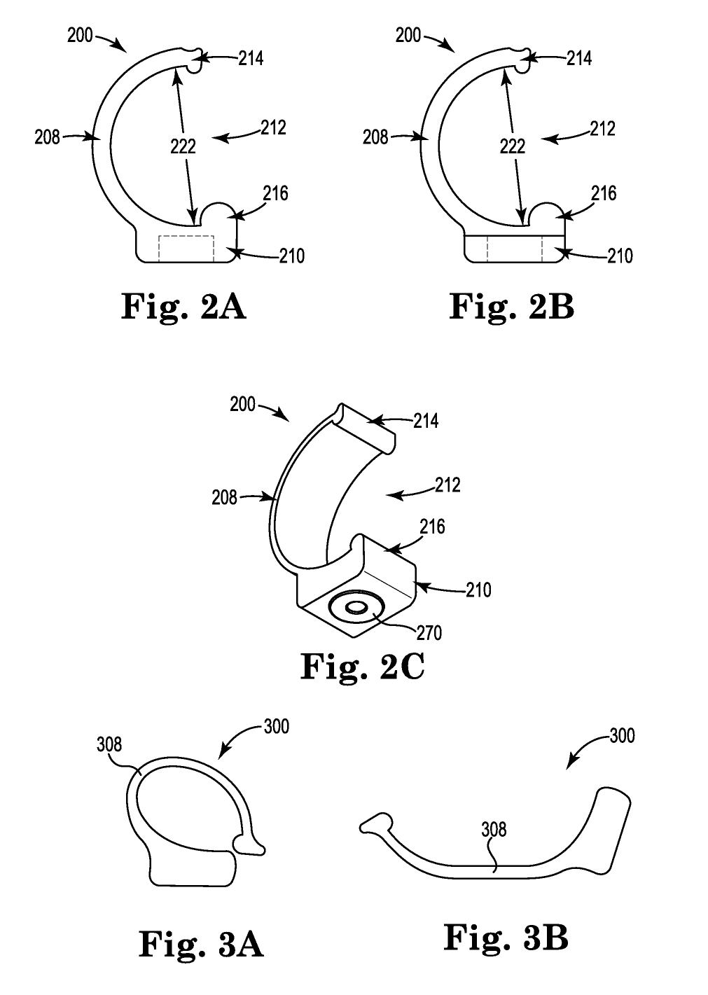

According to one aspect of this embodiment, as illustrated in FIG. 2A, a holder portion 208 and a base portion 210 of a mount 200 together can be a single component in that they are integrally formed or of monolithic construction. Advantageously, single component mounts 200 are capable of providing improved functionality as compared to conventional mounting apparatus. Surprisingly, such single-component mounts 200 are capable of effectively securing a device or range of devices therein without requiring use of additional parts (e.g., mechanical fasteners or tensioning devices) to provide constraining or tensioning properties necessary to single-handedly and effectively secure the device as desired.

According to another aspect of this embodiment, as illustrated in FIG. 2B, a holder portion 208 and a base portion 210 of a mount 200 are formed as two individual components 208, 210. That is, the mount 200 is an assembly of distinct and/or separable components, collectively forming the holder portion 208 and the base portion 210 of the mount 200 according to this aspect of the invention.

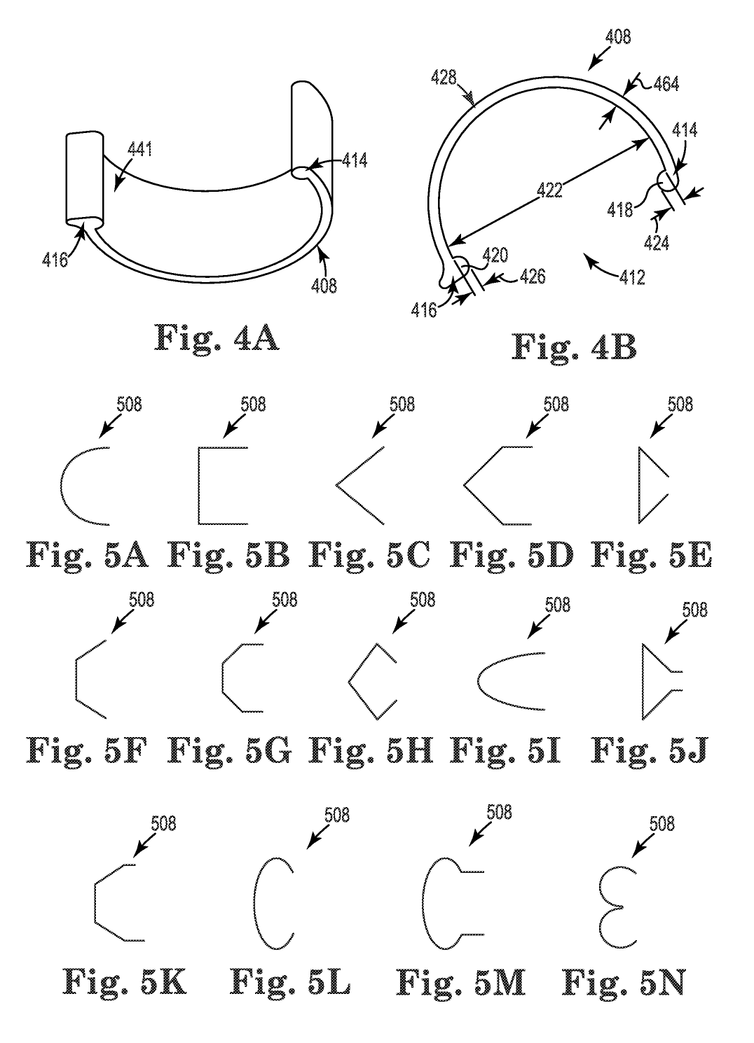

Advantageously, this latter aspect of the invention facilitates use of a base portion 210 with interchangeable holder portions 208, each of which may be designed for use with specific devices or ranges of devices. A product range for holder portions 208 of a mount may include, for example, holder portions 208 having multiple maximum inner diameters 222 (as defined further below with respect to maximum inner diameter 422 in FIG. 4B) that can collectively be used with a wide range of devices of one or more device types. For example, a specific-sized holder portion 208 can secure a phone-sized device, whereas a different specific-sized holder portion 208 can secure a tablet-sized device according to this aspect of the invention. In that manner, a base portion 210 may be attached to a surface and different devices, each having an associated holder portion 208 compatible with that base portion 210, and can be easily and quickly interchanged within such mounts 200 of the invention.

The devices and their associated holder portions 208 can be similar or different according to varying aspects of this embodiment. For example, two individuals with similar cellular phones and associated holder portions 208 can efficiently and interchangeably secure their phones at the same location on a surface by attaching the phone's respective holder portion 208 to the base portion 210 to complete the mount 200. This may be the case when the mount 200 is used in a fitness facility, for example, where fitness equipment is successively used by multiple individuals desiring to access their device while using the equipment. As another example, one individual with multiple device types, each device having a different type of holder portion 208, can efficiently and interchangeably secure those devices at the same location on a surface by attaching the device's respective holder portion 208 to the base portion 210 to complete the mount 200. This may be the case when the mount 200 is used at the individual's workstation, for example, where successive use of different devices at the same location on a surface is desired throughout the day.

In an alternate embodiment, this latter aspect of the invention facilitates use of a holder portion 208 with interchangeable base portions 210 or sub-components 270 thereof, each of which may be designed for attachment to a different surface. In that manner, multiple base portions 210 or sub-components 270 thereof can be attached to different surfaces and a device having an associated holder portion 208 compatible with those base portions 210 or sub-components 270 thereof, can be easily and quickly interchanged within such mounts 200 of the invention. Recognize also that interchangeability of base portions 210 according to this embodiment may entail interchanging only one of multiple sub-components 270 constituting the base portion of the mount. In an exemplary embodiment, a base portion 210 of a mount comprises a universal base attachment mechanism (for example, 270) for quick and simple attachment of the mount 200 in its entirety to a range of surfaces indirectly through an adapter (not shown).

Base portions 210 or adapters used in conjunction therewith for attachment of the mount 200 to a surface include any suitable attachment mechanisms depending on desired applications. The number of attachment mechanisms suitable for use with mounts 200 according to the present invention is unlimited and can include, for example, one or more of the following attachment mechanisms: clamp, screw, plate hemisphere, ring, bracket (e.g., snap- flat-, or U-bracket), band (e.g., elastic band), interlock, screw clamp, and clip. If desired, any of a wide variety of conventional adapters may be used with mounts 200 of the invention, including the following exemplary fasteners: bolts (e.g., U-bolts), snaps, nails, rivets, staples, cable holders (including, for example, self-closing, press-in, snap-lock, locking-arm, adjustable-strap, adjustable-loop, fold-over strap, flexible-loop, and adjustable-strap cable holders), straps, ties (e.g., zip-ties), tape (e.g., double-sided foam tape available from 3M Company (St. Paul, Minn.) under the VHB trade designation), hook-and-loop, clamps (e.g., bar clamps, band clamps, corner clamps, plier clamps, spring clamps, and tube clamps), tool holders, hinges, suction cups, tongs, pliers, grippers, hangars, and collars. Many off-the-shelf adhesives may also be used for attachment of the mount 200 to a surface. Exemplary adhesives include those classified as one or more of the following adhesive types: epoxy, sealant, caulking, glue (e.g., super glue), or hot-melt.

The base portions 210 can be similar or different according to varying aspects of this embodiment. For example, a base portion 210 attached to a stationary bike may have a different design than a base portion 210 attached to a weight bench. This may be the case when an individual is proceeding through various stations within a fitness facility and desires to access the same device at multiple locations within the facility. As another example, one individual can efficiently and interchangeably secure the same device within mounts 200 of the invention by attaching the device and its associated holder portion 208 to one of several base portions 210 attached to different surfaces to complete the mount 200. This may be the case when the mount 200 is used throughout an individual's day at various locations and for various activities. For example, an individual may successively attach a cellular phone and its associated holder portion 208 to a base portion 210 attached to a surface of an automobile, a workstation, various pieces of exercise equipment, or a kitchen, as often used throughout the day.

Conventional mounting apparatus often include multiple and complex parts. The fact that a mounting apparatus can be made and work effectively as a single component or a combination of more than one relatively simple component is one advantage of the present invention. Partly due to the absence, within the mount, of parts requiring movement with respect to each other in order to provide constraining or tensioning properties necessary to single-handedly and effectively secure a device therein as desired, preferred embodiments of the mount have relatively high durability as compared to many conventional mounting apparatus. In an exemplary embodiment, a mounting apparatus of the invention can survive a freefall drop of 30 meters (100 feet) without any measurable damage. In addition, preferred embodiments of the mount are waterproof and oil-resistant as compared to many conventional mounting apparatus.

A holder portion 208 of the mount 200 is generally shaped in a non-linear manner when viewed from the side, as illustrated in FIGS. 2A-2B, for example. When viewed from the front or back, however, the holder portion 208 is generally shaped in a linear manner (e.g., such that it is rectangular-shaped like the mount 100 in its entirety as illustrated in FIG. 1C) according to a preferred embodiment. The holder portion 208 is shaped such that is extends around three sides of a device (e.g., the back 140 and adjacent sides 150 of the device 102 as illustrated in FIGS. 1F-1G) secured therein. Generally, a device 102 is secured within a holder portion 208 of a mount 200 such that the width dimension 146 of the device 102 (as illustrated in FIG. 1F) is substantially within the confines of the holder portion 208 and spans an opening 212 between opposing ends 214, 216 of the holder portion 208. When the device 102 is secured therein, as illustrated in FIGS. 1D-1G, the holder portion 208 does not extend substantially around a front side 106 of the device 102. That is, the holder portion 208 preferably does not obscure a screen 103 used for display of images and/or data on a front side 106 of the device 102, as is often present on many consumer electronic devices. In a preferred and exemplary embodiment, as illustrated in FIG. 1F, the device 102 extends in a transverse direction from opposing sides 153 of the holder portion 108 of the mount 100.

As compared to many conventional mounting apparatus, a holder portion 108 of the mount 100 constrains (i.e., makes physical contact with) a device 102 only along a portion of two longest opposing side edges 151 of the device 102 (e.g., along about 5% to about 70% of the length dimension 147, more preferably about 20% to about 50% of the length dimension 147 of the device 102) secured within the mount 100 according to exemplary embodiments of the invention. As the width dimension 146 of most devices 102 is typically smaller than its length dimension 147, mounts 100 of the invention are generally smaller than conventional mounts designed to accommodate the length dimension 147 of a device 102. This not only results in a smaller footprint for the mount 100, but it also facilitates mounts 100 that are relatively lightweight. For certain uses, such as bicycling, weight of the mount 100 is very important. Although weight of the mount 100 can vary depending on factors such as the materials used therein, in an exemplary embodiment, a mount 100 of the invention has a mass of less than about twenty (20) grams. In a further exemplary embodiment, a mount 100 of the invention has a mass of less than about twelve (12) grams.

With reference to FIGS. 2A-2C and 3A-3B, the holder portion 208 of the mount 200 is flexible. In one embodiment, the holder portion 208 can be flexed inward (i.e., such that opposing ends 214, 216 of the holder portion 208 move closer together, even to the point of overlapping in some embodiments) and outward (Le., such that opposing ends 214, 216 of the holder portion 208 move farther apart from their normal position in a relaxed state wherein no pressure is exerted on the holder portion 208), even to the point where the opposing ends 214, 216 move closer together in the opposite direction after the holder portion 208 is flexed into an approximately straight line). According to one aspect of this embodiment as illustrated in FIG. 3A, the holder portion 308 of the mount 300 can be flexed inward from its relaxed state to an overlapping position. According to another aspect of the embodiment as illustrated in FIG. 3B, the holder portion 308 of the mount 300 can be flexed outward from its relaxed state without significantly impacting the mount's ability to effectively secure an intended device therein. This property beneficial enables mounts 300 of the invention to be efficiently used with a wide range of devices. Not only are mounts 300 of the invention capable of such flexible securement of devices, but preferred mounts 300 of the invention exhibit such properties even after repeated flexure and use—i.e., the holder portion 308 of such mounts 300 is fatigue resistant as described above. Such holder portions 308 within mounts 300 of the invention advantageously provide improved functionality as compared to conventional mounting apparatus.

The width 160 of the mount 100 (i.e., when the mount 100 is attached to a surface in an upright position with the base portion 110 of the mount 100 underneath the holder portion 108 of the mount 100 as illustrated in FIGS. 1C-1D) varies according to the type of device and nature of the surface to which the mount 100 is attached. In an exemplary embodiment, width 160 of the mount 100 is about 1.3 centimeters (0.5 inch) to about 7.6 centimeters (3.0 inches). In further exemplary embodiments, width 160 of the mount 100 is about 2.5 centimeters (1.0 inch), 3.2 centimeters (1.25 inches), or 4.4 centimeters (1.75 inches).

Similarly, the height 162 of the mount 100 varies according to the type of device and nature of the surface to which the mount 100 is attached. The height 162 of the mount 100 also depends on dimensions of the holder portion 108. In an exemplary embodiment, height 162 of the mount is about 6.7 centimeters (2.6 inches) in a relaxed state (i.e., when no pressure is exerted on the holder portion 108, outwardly from a device therein or inwardly by applying pressure thereto), but increases up to about 10.2 centimeters (4 inches) when a device is secured therein.

An exemplary embodiment of a holder portion of a mount according to the present invention is illustrated in FIGS. 4A-4B. Importantly, dimensions of a holder portion 408 of the mount vary according to the type of device and nature of the surface to which the mount is attached. Although a device can be tilted once secured within a device, devices are generally secured within mounts of the invention such that the device is constrained at the maximum inner diameter 422 of the holder portion 408 of the mount. Maximum inner diameter 422 of a holder portion 408 is measured with respect to the holder portion 408 in a relaxed state (i.e., when no pressure is exerted on the holder portion 408, outwardly from a device therein or inwardly by applying pressure thereto). Maximum inner diameter 422 of a holder portion 408 can vary depending on overall size form factor of the mount, which in turn is influenced by device size range for which it is designed.

In all embodiments, the maximum inner diameter 422 of the holder portion 408 is smaller than the width of a device capable of being secured within the mount, so that insertion of the device in the holder portion 408 of the mount causes widening (also referred to herein as dilation) of the opening 412. This dilation is counter-balanced by the resistance to expansion of the holder portion 408. As a result, a clamping force is exerted on the device substantially radially inward by opposing edges 414, 416 of the holder portion 408. When configured for securing a range of device sizes or device types therein, maximum inner diameter 422 of the holder portion 408 is generally determined by device width of devices or ranges of devices to be secured therein. Typically, phone-sized devices have a width that falls within the 2.5-8.9 centimeters (1.0-3.5 inches) (“small”) range; GPS-sized devices have a width that falls within the 6.4-12.7 centimeters (2.5-5.0 inches) (“medium”) range; and tablet-sized devices have a width that falls within the 10.2-20.3 centimeters (4.0-8.0 inches) (“large”) range. As such, in an exemplary embodiment, maximum inner diameter 422 of a holder portion 408 is selected such that the holder portion 408 can flex through the width range of a specific device class (e.g., small, medium, or large) and provide the proper holding force throughout flexion to any device within that class.

In a preferred embodiment, there are no mechanical parts in the holder portion of the mount. As such, effectiveness of the holder portion of the mount in securing intended devices often derivates from the material it is constructed from. Preferred materials for the holder portion balance flexure with holding force of the holder portion. In a preferred embodiment, Young's Modulus of the material is about 0.1-8.0 GPa, and the ultimate tensile strength of the material is about 12-90 MPa. This balance of material properties allows for a desired range in flexure over the variation in device size to provide a desired holding force. Holding force through flexion can be, for example, about 8-67 Newtons.

The overall thickness 464 of the holder portion 408 of the mount depends upon the flexibility and strength of the material from which it is formed. Although substantially the same throughout the holder portion 408 illustrated in FIGS. 4A-4B, the thickness 464 can vary throughout the holder portion 408. For a material with a Young's modulus of less than about 1 GPa and an ultimate tensile strength of less than about 20 MPa, a holder portion 408 has a maximum thickness 464 of about 0.50 centimeter (0.20 inch) to about 0.60 centimeter (0.25 inch) in an exemplary embodiment. In another exemplary embodiment, the holder portion 408 has a maximum thickness 464 of about 0.25 centimeter (0.10 inch) to about 1.20 centimeters (0.50 inch). In another exemplary embodiment, the holder portion 408 has a maximum thickness 464 of 0.25 centimeter (0.10 inch) to about 2.54 centimeters (1.0 inch).

In one embodiment, such as that illustrated in FIGS. 4A-4B, the holder portion 408 has protrusions 418, 420 (also referred to herein as ridges) at each respective opposing edge 414, 416 of the holder portion 408 adjacent the opening 412 of the holder portion 408 (comparable to serifs on a typeface letter “C” in an exemplary embodiment where the holder portion 408 is C-shaped). The size of the protrusions 418, 420 can vary according to, for example, the maximum inner diameter 422 of the holder portion 408. While it can vary, in one embodiment, the range for pinch point height 424, 426 for respective protrusions 418, 420 is about 1.5 millimeters (0.06 inch) to about 0.6 centimeter (0.24 inch).

When protrusions 418, 420 are present, it is advantageous for the inner surface 421 of the holder portion 408 immediately adjacent the protrusions 418, 420 (and hence, edges of a device secured in the mount by physical contact at that location) to slope inward (i.e., toward the center 428 of the holder portion 408), so that a clamping force exerted by the holder portion 408 forces the device outward toward the opposing edges 414, 416 of the holder portion 408 surrounding the opening 412. In this manner, the device is forced against the protrusions 418, 420 of the holder portion 408 to improve secure seating of the device within the mount.

Note that, as a result of the holder portion's curved inner surface 428 in the embodiment illustrated in FIGS. 4A-4B, the maximum inner diameter 422 of the holder portion 408 extends between points substantially adjacent the protrusions 418, 420. The maximum inner diameter 422 of the holder portion 408 is smaller than the width of a device capable of being secured within the mount, so that insertion of the device in the holder portion 408 of the mount causes widening (also referred to herein as dilation) of the opening 412. This dilation is counter-balanced by the holder portion's resistance to expansion. As a result, a clamping force is exerted on the device substantially radially inward by the protrusions 418, 420 at their diametrically opposed positions. When present, the protrusions 418, 420 provide pinch points (also referred to herein as jaws), further enhancing resistance to sliding movement of the device when clamped in such a holder portion 408.

In one embodiment, the holder portion 508 has a non-linear (e.g., semi-circular or major arc) side profile when viewed along its longitudinal axis as illustrated in FIG. 5A, but comprises only about half of the circumference or outer perimeter of such a profile that would be present if the profile was symmetrically enclosed—i.e., without an opening. For example, when the holder portion 508 has a semi-circular side profile, the holder portion consists of about 180°+/−5° of a circle.

While an exemplary holder portion 508 described herein is generally C-shaped as illustrated in FIG. 5A, different profiles may be adopted for the holder portion of mounts of the invention. Other suitable holder portion 508 profiles include, for example, those shaped as a block C (FIG. 5B), V (FIG. 5C), half hexagon (FIG. 5D), angle in (FIG. 5E), angle out (FIG. 5F), half octagon (FIG. 5G), open diamond (FIG. 5H), U (FIG. 51), angle in gripper (FIG. 5J), angle out gripper (FIG. 5K), tall C (FIG. 5L), tall C gripper (FIG. 5M).

According to a further embodiment, the holder portion secures multiple devices within the mount. For example, the holder portion 508 comprises a flexible, W-shaped portion of the mount according to one aspect of this embodiment, as illustrated in FIG. 5N.

As with all embodiments of the invention, holder portions 508 shaped as such may or may not include protrusions. If protrusions are present, recognize that the profiles illustrated in FIGS. 5A-5N would be modified accordingly.

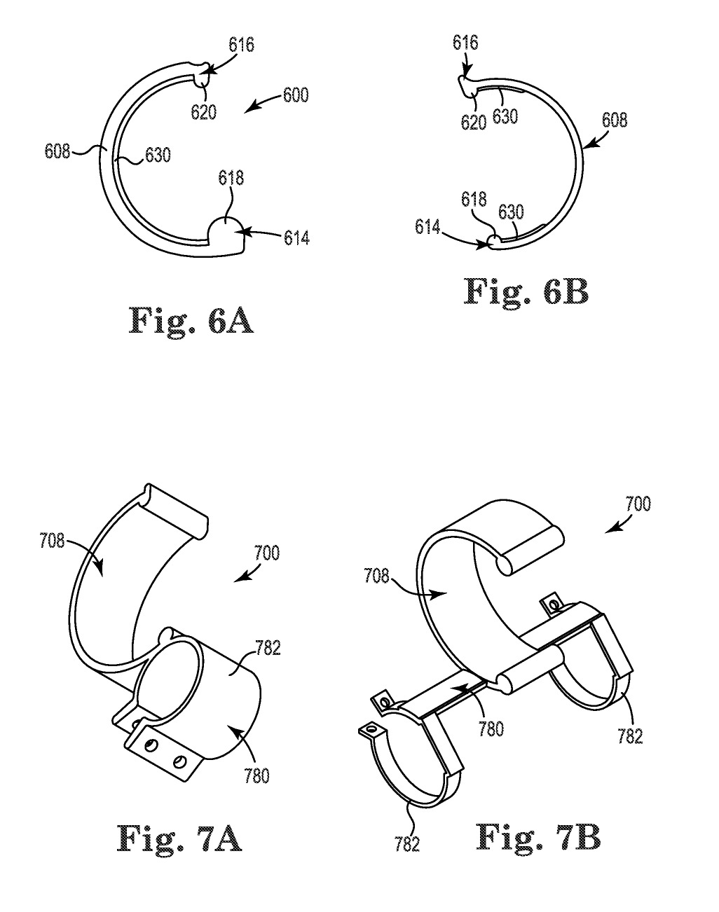

According to a further embodiment as illustrated in FIGS. 6A-6B, the holder portion 608 of the mount 600 comprises a gripping component 630 on at least a portion thereof. The gripping component 630 can include one or more discrete parts. In one embodiment, a gripping component 630 is provided on the holding portion 608 at a position or multiple positions designed to contact a device secured therein. In an exemplary embodiment, as illustrated in FIG. 6A, the gripping component 630 is provided on substantially the entire inner surface of the holder portion 608, extending toward opposing edges 614, 616 of the holder portion 608 adjacent respective protrusions 618, 620. In an exemplary embodiment as illustrated in FIG. 6B, the holder portion 608 comprises a gripping component 630 at radially opposing inner surfaces adjacent opposing edges 614, 616 of the holder portion 608, locations typically making physical contact with a device when secured therein.

If included within the mount, the gripping component 630 generally increases the coefficient of friction between the mount and a device with which it is used. As such, the gripping component 630 facilitates a reduction in slip between the device and the mount as compared to slip between the device and a similar mount, but without the gripping component 630. The gripping component 630 also facilitates translation of a device once secured within a mount as described above.

An exemplary material for use as the gripping component 630 is a flexible and fatigue resistant material as described above with respect to the holder portion of the mount, but a material that is softer than material used for the holder portion of the mount. Such a material is referred to herein as a grip material. Preferably, a grip material used in accordance with the present invention has less than about 25% compression set (i.e., the amount of permanent deformation that occurs when a material is compressed to a specific deformation, for a specified time, at a specific temperature) after being compressed at room temperature for about 22 hours when tested according to ASTM D 395. In one embodiment, grip material within a mount has a Shore D hardness of less than about 55. In other embodiments, grip material within a mount has a Shore A hardness of about 3090. Thickness of the gripping component is influenced by hardness of the grip material used therein. In an exemplary embodiment, the gripping component has a maximum thickness of about 1.30 millimeters (0.05 inch) to about 1.30 centimeters (0.5 inch). In a further exemplary embodiment, the gripping component has a maximum thickness of less than about 6.35 millimeters (0.25 inch). However, thickness of the gripping component can vary.

The base portion of the mount can be attached to a surface directly or via one or more components. The nature of the components is often determined by the nature of the surface to which the mount is attached and the type of attachment mechanism desired.

As illustrated in FIGS. 2A-2C, the base portion 210 comprises a magnetic sub-component 270 according to one embodiment, facilitating magnetic attachment of the mount 200 to a surface (e.g., a ferrous surface such as iron or steel). The use of a flush-mounted magnetic sub-component 270 as illustrated in FIGS. 2A-2C facilitates increased functionality of the mount 200, particularly when attached to a ferrous surface. A mounting apparatus 200 of the invention, when magnetically attached to a surface as such, can exhibit the following degrees of freedom with respect to its orientation on the surface: sway (translation to the right and left), surge (translation forward and backward), and yaw (rotation by turning the mount from side to side). These degrees of freedom are limited only by the shape and configuration of the surface to which the mount is attached. For example, the mount 200 can have a limitless yaw of 360 degrees in both directions, irrespective of whether a device is secured within the mount 200.

Many types of magnetic components may be used within mounts of the invention, including rare earth and other types of permanent magnets, electromagnets, superconductors, and others known to those of ordinary skill in the art. Exemplary magnets comprise the following: neodymium iron boron (also referred to as NdFeB or NIB), samarium cobalt (SmCo), alnico (i.e., one or more of a family of iron alloys, which in addition to iron, are composed primarily of aluminum (Al), nickel (Ni), and cobalt (Co)), or ceramics (e.g., ferrites). Although magnets can be custom-manufactured into any desired shape, many off-the-shelf shapes may be used—e.g., bars (rounded bars), prisms, horseshoes, donuts, rings, disks, plates, rods, spheres, and hemispheres.

According to other embodiments, the base portion 110 facilitates attachment to a surface 104 using non-magnetic mechanisms. In its simplest form, gravity provides the non-magnetic attachment mechanism. Depending on the material from which the base portion 110 of the mount 100 is formed and the dimensions of the same, for example, the base portion 110 may be selectively weighted to facilitate effective attachment of the mount 100 with a device secured therein to a substantially horizontal surface 104 simply by placing the mount 100 on the surface 104 so that the holder portion 108 extends upward from the base portion 110 of the mount 100 as illustrated in FIG. 1D.

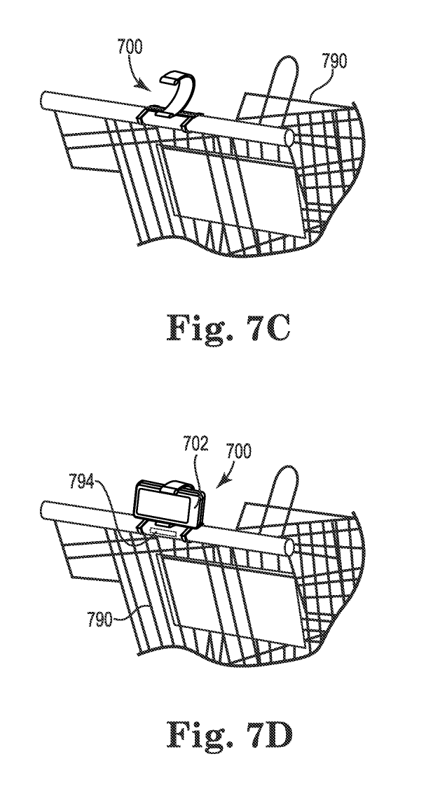

Other exemplary non-magnetic attachment mechanisms and, thus, components of the base portion in alternate embodiments of the invention include mechanical and adhesive mechanisms and components. In an exemplary embodiment, as illustrated in FIG. 7A, the base portion 780 comprises a component functioning as a clamp 782 for attachment of the mount 700 directly to a surface of an object having a rounded cylinder shape. According to a further embodiment, as illustrated in FIG. 7B, the base portion 780 comprises multiple clamps 782. Such a configuration was found useful when, for example, attaching the mount to the handlebar on a shopping trolley, as illustrated in FIGS. 7C-7D. Sometimes shopping trolleys 790 and other objects have branding, advertisements, or physical obstructions making attachment of a mount 700 at the desired location (e.g., the center of the handlebar 792) difficult. When the mount 700 is configured with multiple clamps 782, however, it can be attached so that a device 702 secured therein is positioned as desired, irrespective of such obstructions and without obscuring such branding/advertisements 794.

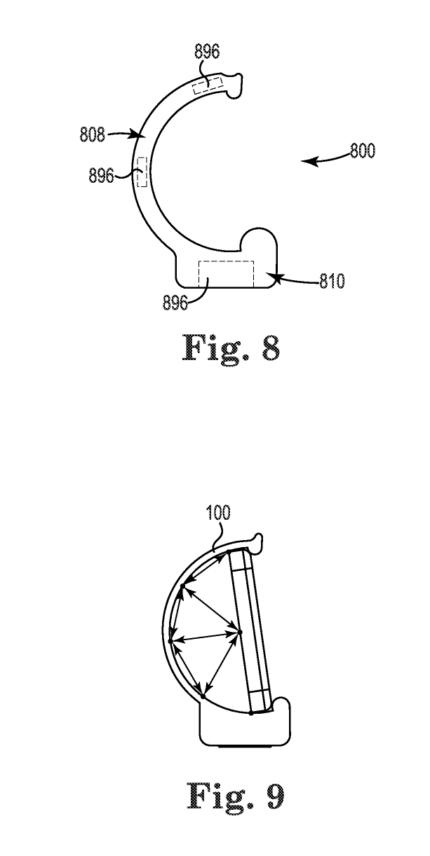

According to a further aspect of the invention, the mount is enabled for data communication, e.g., for wireless and/or radio communication, with the electronic device. In one embodiment, the mount comprises communications functionality enabling communication of data between the mount and an electronic device used with the mount. While not limited thereby, FIG. 8 illustrates an exemplary embodiment of such a mount 800. At least one of the base portion 810 and the holder portion 808 comprises communications functionality 896. The communications functionality 896 may be placed at only one location within the mount 800, or it may be placed at several locations as illustrated in FIG. 8.

Communications functionality may be provided by one or more electronic communication components selected from, for example, one or more components enabling communication via: near field communication (NFC), radio-frequency identification (RFID), short-wave radio frequency (e.g., Bluetooth), wireless local area network (WLAN) (e.g., Wi-Fi), cellular data service, mobile satellite communication, or Global Positioning System (GPS). Exemplary components for providing communications functionality include, for example, NFC and/or RFID programs embedded on a NFC chip or RFID tag. Suitable electronic communication components for providing such functionality are commercially available from a number of sources. For example, components enabling NFC communication include those marketed by NXP Semiconductors under the following trade designations: PN512 (transmission module), PN531 (transmission module), and PN544 (NFC controller). Components enabling RFID communication include those sold by Texas Instruments Inc. (Plano, Tex.) under the following trade designations: TI-RFid tags, TI-RFid smart labels, and TI-RFid reader systems.

Again, depending on the type of communication, for example, one or more components may be necessary to provide desired communications functionality. The communications functionality (i.e., components therefor) can be positioned at any suitable location, some of which are described above with respect to FIG. 8. In one embodiment, such functionality is housed within the mount such that it is not visible or easily accessible on the exterior of the mount during use. When the communications functionality is based on NFC communications, for example, this embodiment is an improvement over conventional placement of NFC chips on articles using, for example, adhesive-backed stickers repositionably placed on exterior surfaces of the articles. Not only do such stickers tend to accumulate grime on the adhesive, causing them to lose their ability to adequately adhere to a surface, placement of NFC chips in such a manner allows users of devices in communication with such NFC chips to more easily relocate the sticker so that unwanted communication ceases, as may be the case when advertising materials are communicated to users of devices via strategically placed NFC chips. In another embodiment, communications functionality is at least partially located so that it is visible on the exterior of the mount during use.

When housed within the mount, one or more components necessary to provide communications functionality can be integrally formed within the mount during, for example, manufacture of the mount or individual components thereof. In one embodiment, such components are confined to the holder portion; and, in another embodiment, such components are confined to a base portion. In another embodiment, such components are included within both the holder portion and the base portion of the mount.

In one embodiment, communications functionality is provided by passive components. An advantage of passive components, such as NFC chips and RFID tags, is that they do not contain or require a power source. This enables such components to be fully integrated within a mount. According to one aspect of this embodiment, passive components are integrated within a mount during molding of plastic material into the shape of the mount or component thereof. According to this embodiment, the communications functionality is limited to nonprogrammable actions, operating based on one or more preset programs. According to another aspect of this embodiment, the communications functionality encompasses programmable actions, operating based on at least one programmable program and, optionally, one or more preset programs.

In another embodiment, communications functionality is provided by active components, components which require a power source. According to one aspect of this embodiment, the communications functionality provides programmable actions, operating based on at least one programmable program and, optionally, one or more preset programs. According to another aspect of this embodiment, the communications functionality is limited to nonprogrammable actions, operating based on one or more preset programs.

A benefit of a communication-enabled mounting apparatus is that it permits customizable, automatic, site-specific configuration or operation of an electronic device. A user may, for example, have a number of the mounts mounted in a number of respective locations. A preset program may be user-customizable in certain embodiments, facilitating custom device configuration and/or device/mount interaction.

In one embodiment, a mount's communications functionality may trigger automatic configuration of a device according a user's customized settings. Configuration of a device by changing system settings for power management and/or privacy purposes, for example, can thus be effected through automatic, site-specific configuration triggered by respective mounts.

An exemplary preset program is one capable of automatically activating an application management utility on the device. For example, a user may preset application management utility software on a device to switch on GPS communication and enable a navigation app. According to an exemplary aspect of this embodiment, a component (e.g., a NFC chip) within a mount communicates with a device (e.g., a NFC-enabled device) to switch on its GPS communication and enable a navigation app thereon when there is communication between a receiver on the device and the communications functionality component on the mount. Basic functionality of, for example, NFC communications triggering management utility actions is well known and understood by persons of ordinary skill in the art.

The number of communication possibilities is immense. A mount attached, for example, to a user's bicycle may be programmed to automatically launch an exercise application (optionally, relating specifically to cycling) on the device. Alternatively, communications functionality within such a mount may trigger automatic configuration of a cellular phone held in the mount—e.g., switching on GPS services, switching off Wi-Fi capability, etc.

As another example, a mount may be attached to and kept, for example, at a workstation or desk. Such a communication-enabled mount may, for example, be programmed to automatically launch one or more work-related applications on the device. Alternatively, communications functionality within the mount may trigger automatic configuration of a device held in the mount. For example, if a device does not have adequate cellular phone reception in an office, a mount positioned on a workstation or desk in the office can trigger automatic configuration of a cellular phone held in the mount to switch off cellular data communication by the device.

As another example, brick-and-mortar vendors may attach mounts having location-enabled communications functionality to shopping trolleys. Such mounts can be programmed to automatically launch store-specific or department-specific applications or transfer data to a device that is relevant to the particular store or department therein. In an exemplary embodiment, trolley-mounts according to the invention include communications functionality programmed to automatically trigger connection (e.g., using Wi-Fi) of a device mounted therein to a store's Internet website or other network. Connecting a device in this manner can facilitate transmission of, for example, advertising material, product prices and deals, store-specific barcode information, and the like. Advantageously, using mounts of the invention, access to such electronic information is more easily accessible via devices secured therein. Functionality of store- and department-specific applications is, thus, increased accordingly. By facilitating access to store- and department-specific applications and data in this manner, stores can advantageously draw upon mounts of the invention to increase sales or otherwise generate more revenue.

In some embodiments, communications functionality within a mount may be locked so that communications with a device are limited to execution of predefined actions that cannot be redefined by the device or its user. For example, when a communication-enabled mount is attached to a shopping trolley, such an embodiment may be desirable to avoid multiple users of devices secured within such mounts from interfering with desired communications—e.g., advertising material displayed.

In further embodiments, mounting apparatus of the invention comprise space for marketing and advertisement. Mount can be made with various colors and designs (e.g., printed, stamped, machined, or molded). In an exemplary embodiment, mounts of the invention comprise embedded branding, e.g., using colors and designs formed using in-mold graphics and/or film-applied graphics (e.g., by application of ethyl vinyl acetate (EVA)-based polymer films with embedded graphics).

This may be particularly beneficial in applications, such as those where the mount is secured to a shopping trolley 790, as illustrated in FIG. 7C. On a shopping trolley 790, or other similar semi-permanent location with high traffic, marketers may wish to place advertisements on the mount 700. To facilitate the same, the mount 700 can be constructed with a removable and replaceable advertising display device, such as an insert for interchangeable ads. Advertising material carried by the mount 700 may also include a molded, stamped, or printed branding and/or advertisements.

When designed according to preferred embodiments of the invention, the mount has a relatively simple form factor with one or more surfaces (e.g., surface 796 illustrated in FIG. 7C), providing conveniently-shaped, highly-visible advertising display surfaces on which advertising information and/or indicia may be displayed. The mount itself can also be used as promotional item or as a branded give-away.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. In addition, the lack of mention or discussion of a feature, step, or component provides the basis for claims where the absent feature or component is excluded by way of a proviso or similar claim language. Further, as used throughout, ranges may be used as shorthand for describing each and every value that is within the range. Any value within the range can be selected as the terminus of the range. Similarly, any discrete value within the range can be selected as the minimum or maximum value recited in describing and claiming features of the invention.

Finally, as discussed herein it is again noted that the mounts and portions thereof described herein may comprise all components in one or multiple parts. Further, any material or performance properties described or measured herein are those existing at room temperature and atmospheric pressure unless specified otherwise.

1. A mounting apparatus for securing an electronic device to facilitate operation of the device by a user in a hands-free manner, the mounting apparatus comprising:
a base portion configured for attachment of the mounting apparatus to a surface; and
a holder portion comprising a flexible and fatigue resistant material adjacent the base portion and configured to enable single-handed securing of the device therein by constraining the device only along a portion of two longest opposing side edges of the device without substantially obscuring a front side of the device and such that a gap exists between a back side of the device and the holder portion,
wherein the holder portion has a maximum inner diameter in a relaxed state that is smaller than a width dimension of the device.

2. The mounting apparatus of claim 1, wherein the mounting apparatus is a single component comprising the base portion and the holder portion.

3. The mounting apparatus of claim 1, wherein the mounting apparatus comprises at least two components, one of the at least two components comprising the base portion and another one of the at least two components comprising the holder portion.

4. The mounting apparatus of claim 1, wherein the mounting apparatus is capable of use with a range of small devices, wherein width of the devices in the range is about 2.5-8.9 centimeters.

5. The mounting apparatus of claim 1, wherein the mounting apparatus is capable of use with a range of medium devices, wherein width of the devices in the range is about 6.4-12.7 centimeters.

6. The mounting apparatus of claim 1, wherein the mounting apparatus is capable of use with a range of large devices, wherein width of the devices in the range is about 10.2-20.3 centimeters.

7. The mounting apparatus of claim 1, wherein the width of the holder portion is about 1.3 centimeters to about 7.6 centimeters.

8. The mounting apparatus of claim 1, wherein the gap provides a distance between the back side of the device and the mount of about 1.0 centimeter to about 2.4 centimeters.

9. The mounting apparatus of claim 1, wherein Young's Modulus of the flexible and fatigue resistant material is about 0.1-8.0 GPa.

10. The mounting apparatus of claim 1, wherein ultimate tensile strength of the flexible and fatigue resistant material is about 12-90 MPa.

11. The mounting apparatus of claim 1, wherein the mount is capable of providing a holding force through flexion of about 8-67 Newtons when the device is secured within the mount.

12. The mounting apparatus of claim 1, wherein the holder portion has a maximum thickness of 0.25 centimeter to about 2.54 centimeters.

13. The mounting apparatus of claim 1, wherein the holder portion has at least one protrusion at each of two opposing edges adjacent an opening of the holder portion.

14. The mounting apparatus of claim 13, wherein an inner surface of the holder portion adjacent the opposing protrusions slopes inward.

15. The mounting apparatus of claim 1, further comprising a gripping component on at least a portion of an inner surface of the holder portion.

16. The mounting apparatus of claim 15, wherein the gripping component comprises a material having a Shore D hardness of less than about 55.

17. The mounting apparatus of claim 15, wherein the gripping component comprises a material having a Shore A hardness of about 3090.

18. The mounting apparatus of claim 15, wherein the gripping component has less than about 25% compression set after being compressed at room temperature for about 22 hours when tested according to ASTM D 395.

19. The mounting apparatus of claim 15, wherein the gripping component has a maximum thickness of about 1.30 millimeters to about 1.30 centimeters.

20. The mounting apparatus of claim 1, wherein the holder portion comprises a material selected from acrylonitrile butadiene styrene, high-density polyethylene, and thermoplastic elastomer materials.

21. The mounting apparatus of claim 1, wherein the device is a portable consumer electronic device.

22. The mounting apparatus of claim 1, wherein the device is selected from personal data assistants, phones, and personal computers.

23. The mounting apparatus of claim 1, wherein the base portion comprises a magnetic sub-component for attachment to the surface.

24. The mounting apparatus of claim 1, further comprising communications functionality housed therein.

25. The mounting apparatus of claim 24, wherein the communications functionality comprises a passive component.

26. The mounting apparatus of claim 25, wherein the communications functionality comprises a NFC chip or RFID tag.

27. The mounting apparatus of claim 24, wherein the communications functionality is limited to nonprogrammable actions, operating based on one or more preset programs.

28. A kit comprising the mounting apparatus of claim 1, wherein the kit comprises:
the base portion; and
at least two of the holder portions, wherein the holder portions are interchangeable with the base portion to form the mounting apparatus.

29. A kit comprising the mounting apparatus of claim 1, wherein the kit comprises:
the holder portion; and
at least two of the base portions, wherein the base portions are interchangeable with the holder portion to form the mounting apparatus.

30. A method of using the mounting apparatus of claim 1, the method comprising:
attaching the mounting apparatus to a first surface;
securing the device therein;
optionally, operating the device in a hands-free manner;
optionally, detaching the mounting apparatus from the first surface;
optionally, attaching the mounting apparatus to a second surface; and
optionally, operating the device in a hands-free manner.

31. The method of claim 30, wherein the device is secured within the mounting apparatus in a generally horizontal orientation.

32. The method of claim 31, further comprising the step of tilting the device from the generally horizontal orientation.

33. The method of claim 30, wherein the mounting apparatus secures the device such that the mounting apparatus functions as a stand from which the device can extend upward.

34. The method of claim 30, wherein the surface comprises a surface on a shopping trolley.

35. The method of claim 30, wherein the device is operated while driving a motorized vehicle.

36. The method of claim 30, wherein the device is operated by a user simultaneously while exercising.

37. A mounting apparatus for securing an electronic device to facilitate operation of the device by a user in a hands-free manner, the mounting apparatus comprising:
a base portion configured for attachment of the mounting apparatus to a surface;
a holder portion adjacent the base portion and comprising a flexible and fatigue resistant material; and
communications functionality housed within at least one of the base portion and the holder portion and enabling data communication between the mount and the device when secured in the mount.

38. The mounting apparatus of claim 37, wherein the communications functionality comprises a passive component.

39. The mounting apparatus of claim 38, wherein the communications functionality comprises a NFC chip or RFID tag.

40. The mounting apparatus of claim 37, wherein the communications functionality is limited to nonprogrammable actions, operating based on one or more preset programs.

41. A shopping trolley comprising the mounting apparatus of claim 37 attached to at least one surface thereon.
